(19) United States
(12) Patent Application Publication
(10) Pub. No.: US 2025/0187032 A1
(43) Pub. Date: Jun. 12, 2025

(54) SUBSTRATE HOLDER, SUBSTRATE HOLDING METHOD, AND FILM-FORMING APPARATUS

(71) Applicant: Resonac Hard Disk Corporation, Chiba (JP)

(72) Inventors: Yasunori WATANABE, Chiba (JP); Masaaki INOUE, Tokyo (JP); Masanori KITAHARA, Tokyo (JP)

(21) Appl. No.: 18/971,923

(22) Filed: Dec. 6, 2024

(30) Foreign Application Priority Data
Dec. 12, 2023 (JP) 2023-209362

(51) Int. Cl. B05B 13/02

(52) U.S. Cl. CPC B05B 13/02

(57) ABSTRACT

A substrate holder according to the present disclosure includes: a hole portion in which a disc-shaped substrate is vertically disposed; and at least four support members attached to the periphery of the hole portion in an elastically deformable manner. Two first support members of the four support members support the disc-shaped substrate at a first-side outer peripheral edge portion and a second-side outer peripheral edge portion of the disc-shaped substrate located in an upper portion of the disc-shaped substrate with respect to a vertical direction. Two second support members of the four support members support the disc-shaped substrate at a third-side outer peripheral edge portion and a fourth-side outer peripheral edge portion of the disc-shaped substrate located in a lower portion of the disc-shaped substrate with respect to the vertical direction.

### CROSS-REFERENCE TO RELATED APPLICATIONS

Priority is claimed to Japanese Patent Application No. 2023-209362, filed Dec. 12, 2023, the entire content of which is incorporated herein by reference.

### BACKGROUND

### 1. Technical Field

The present disclosure relates to a substrate holder, a substrate holding method, and a film-forming apparatus.

### 2. Description of Related Art

A substrate holder for holding a substrate by a plurality of support members has been used in a film-forming apparatus for a substrate. As a film-forming apparatus using such a substrate holder, for example, Japanese Unexamined Patent Publication No. H8-274142 (hereinafter, “Patent Document 1”) discloses an inline film-forming apparatus in which a carrier holding two substrates with their plate surfaces facing sideways in a transport direction is sequentially transported by a transport system to a plurality of vacuum chambers arranged along a polygonal transport path, and a film-forming process is continuously performed by processing means arranged in the vacuum chambers constituting a film-forming process chamber.

Japanese Unexamined Patent Publication No. 2009-277343 (hereinafter, “Patent Document 2”) discloses a film-forming apparatus including a substrate holder that holds an insulating substrate with a pair of a first support member and a second support member, the first support member having a holding member formed to protrude from the inner periphery of an opening of a substrate holder main body toward the inside of the opening and supporting one end of an insulating substrate, the second support member having a holding member supporting the other end of the insulating substrate and movable to protrude toward the inside of the opening or retreat from the inside of the opening.

### SUMMARY

A substrate holder according to the present disclosure includes: a hole portion in which a disc-shaped substrate is vertically disposed; and at least four support members attached to the periphery of the hole portion in an elastically deformable manner. Two first support members of the four support members support the disc-shaped substrate at a first-side outer peripheral edge portion and a second-side outer peripheral edge portion of the disc-shaped substrate located in an upper portion of the disc-shaped substrate with respect to a vertical direction. Two second support members of the four support members support the disc-shaped substrate at a third-side outer peripheral edge portion and a fourth-side outer peripheral edge portion of the disc-shaped substrate located in a lower portion of the disc-shaped substrate with respect to the vertical direction. A central angle of the disc-shaped substrate between an uppermost peripheral edge portion of the disc-shaped substrate located in an uppermost portion of the disc-shaped substrate with respect to the vertical direction and each of the first-side outer peripheral edge portion and the second-side outer peripheral edge portion is 30° to 65°. A central angle of the disc-shaped substrate between a lowermost peripheral edge portion of the disc-shaped substrate located in a lowermost portion of the disc-shaped substrate with respect to the vertical direction and each of the third-side outer peripheral edge portion and the fourth-side outer peripheral edge portion is 10° to 20°.

### BRIEF DESCRIPTION OF THE DRAWINGS

FIG. 1 is a cross-sectional view illustrating an example of a recording medium manufactured by a film-forming apparatus according to an embodiment of the present disclosure;

FIG. 2 is a plan view of a film-forming apparatus according to the embodiment;

FIG. 3 is a side sectional view of chambers in the film-forming apparatus according to the embodiment;

FIG. 4 is a side view of carriers in the film-forming apparatus according to the embodiment;

FIG. 5 is a microscopic image (a photograph substituted for a drawing) illustrating an example of deformation generated in a substrate;

FIG. 6A is a microscopic image of a disc-shaped substrate held and transported by a substrate holder of Example 1, viewed in a thickness direction; and

FIG. 6B is a microscopic image of a disc-shaped substrate held and transported by a substrate holder of Comparative Example 1, viewed in a thickness direction.

### DETAILED DESCRIPTION

In the film-forming apparatuses of Patent Documents 1 and 2, when a substrate transport speed is increased to increase productivity, the substrate may easily fall due to vibration during transfer or acceleration applied to the substrate. Further, when the supporting force of the support member for supporting the substrate is increased as in the carriers of Patent Document 1 and the substrate holder of Patent Document 2 in order to prevent the substrate from falling, the substrate may be easily deformed or damaged.

When observed from the surface direction of the substrate, deformation (a plastically deformed recess, namely a dent) was not observed in the substrate; however, when observed from the thickness direction, scratches generated were observed on the substrate in some cases. Generation of scratches causes dust in a film-forming process for manufacturing a recording medium, and a bias voltage applied from a support member of the substrate holder to the substrate becomes unstable.

According to one embodiment of the present disclosure, a substrate can be prevented from falling, and deformation of or damage to the substrate and generation of a scratch can be suppressed.

The present disclosure includes the following configurations (1) to (7).

(1) A substrate holder includes: a hole portion in which a disc-shaped substrate is vertically disposed; and at least four support members attached to the periphery of the hole portion in an elastically deformable manner. Two first support members of the four support members support the disc-shaped substrate at a first-side outer peripheral edge portion and a second-side outer peripheral edge portion of the disc-shaped substrate located in an upper portion of the disc-shaped substrate with respect to a vertical direction. Two second support members of the four support members support the disc-shaped substrate at a third-side outer peripheral edge portion and a fourth-side outer peripheral edge portion of the disc-shaped substrate located in a lower portion of the disc-shaped substrate with respect to the vertical direction. A central angle of the disc-shaped substrate between an uppermost peripheral edge portion of the disc-shaped substrate located in an uppermost portion of the disc-shaped substrate with respect to the vertical direction and each of the first-side outer peripheral edge portion and the second-side outer peripheral edge portion is 30° to 65°. A central angle of the disc-shaped substrate between a lowermost peripheral edge portion of the disc-shaped substrate located in a lowermost portion of the disc-shaped substrate with respect to the vertical direction and each of the third-side outer peripheral edge portion and the fourth-side outer peripheral edge portion is 10° to 20°.

(2) In the substrate holder described in (1), the support member does not support the disc-shaped substrate at a portion of the disc-shaped substrate except for: a range of the central angle of the disc-shaped substrate between the uppermost peripheral edge portion of the disc-shaped substrate and each of the first-side outer peripheral edge portion and the second-side outer peripheral edge portion; and a range of the central angle of the disc-shaped substrate between the lowermost peripheral edge portion of the disc-shaped substrate and each of the third-side outer peripheral edge portion and the fourth-side outer peripheral edge portion.

(3) In the substrate holder described in (1), a first support member includes: a coil spring arranged within a gap formed at a peripheral part of the hole portion; and a plate spring member that is coupled to the coil spring within the gap and protrudes from the gap toward an inside of the hole portion, the first support member being from among the two first support members.

(4) In The substrate holder described in (3), a spring constant of the coil spring is 0.2 N/mm to 8.0 N/mm.

(5) In the substrate holder described in (1), a second support member has a shape bent in an L shape, the second support member being from among the two second support members, and the spring constant of the second support member is 0.2 N/mm to 8.0 N/mm.

(6) A substrate holding method by a substrate holder includes: a step of supporting, by the substrate holder, a disc-shaped substrate at a first-side outer peripheral edge portion and a second-side outer peripheral edge portion of the disc-shaped substrate located in an upper portion of the disc-shaped substrate with respect to a vertical direction by two support members of at least four support members attached to a periphery of a hole portion in an elastically deformable manner, the disc-shaped substrate being vertically disposed at the hole portion; a step of supporting, by the substrate holder, the disc-shaped substrate at a third-side outer peripheral edge portion and a fourth-side outer peripheral edge portion of the disc-shaped substrate located in a lower portion of the disc-shaped substrate with respect to the vertical direction by other two support members of the fourth support members. A central angle of the disc-shaped substrate between an uppermost peripheral edge portion of the disc-shaped substrate located in an uppermost portion of the disc-shaped substrate with respect to the vertical direction and each of the first-side outer peripheral edge portion and the second-side outer peripheral edge portion and is 30° to 65°. A central angle of the disc-shaped substrate between a lowermost peripheral edge portion of the disc-shaped substrate located in a lowermost portion of the disc-shaped substrate with respect to the vertical direction and each of the third-side outer peripheral edge portion and the fourth-side outer peripheral edge portion is 10° to 20°.

(7) A film-forming apparatus includes: a chamber configured to perform a film-forming process on a disc-shaped substrate; a carrier provided with the substrate holder described in (1) for holding the disc-shaped substrate at least within the chamber; and a transport mechanism configured to transport the carrier.

Hereinafter, embodiments of the present disclosure will be described in detail with reference to the drawings. In the drawings, the same components are denoted by the same reference numerals, and redundant description will be appropriately omitted.

### (Magnetic Recording Medium)

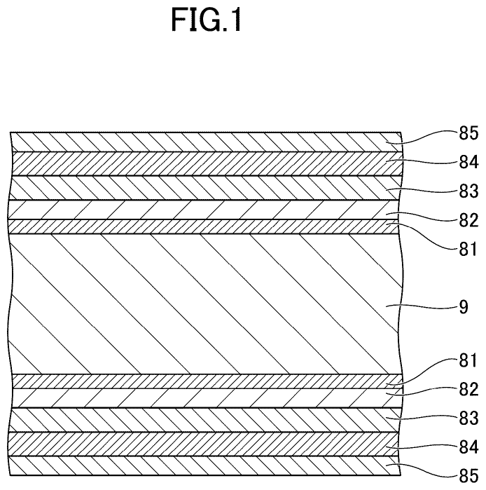

First, an example of a recording medium manufactured by a film-forming apparatus according to the present embodiment will be described. FIG. 1 is a cross-sectional view illustrating an example of a recording medium manufactured by a film-forming apparatus according to the present embodiment. The recording medium is, for example, a magnetic recording medium.

In recent years, the range of application of magnetic recording devices has remarkably expanded, the importance of magnetic recording devices has increased, and the recording density of magnetic recording media used in magnetic recording devices has remarkably improved.

Magnetic recording media are required to achieve higher recording densities in the near future. Therefore, a magnetic layer is required to achieve a high coercive force, a high signal-to-noise ratio (SNR), and a high resolution. In recent years, studies have been made to increase the surface recording density by increasing the track density as well as the improvement of the linear recording density.

As a method for manufacturing a magnetic recording medium, for example, there is a method in which a soft magnetic layer, an intermediate layer, a recording magnetic layer, and the like are formed on a non-magnetic substrate, and then a protective layer is formed on the recording magnetic layer.

It is preferable to continuously perform such a manufacturing method using, if possible, a single film-forming apparatus. Through continuously performing the film formation process, contamination of substrates during handling can be prevented, and the efficiency of the manufacturing process and the product yield can be improved by reducing the number of handling processes, and the productivity in manufacturing magnetic recording media can be increased.

Therefore, for such a manner of manufacturing magnetic recording media, it has been proposed to use an inline film-forming apparatus that sequentially forms magnetic layers and the like on respective surfaces of a non-magnetic substrate while sequentially transporting a carrier holding the non-magnetic substrate between a plurality of chambers.

In order to increase the productivity of the inline film-forming apparatus in manufacturing magnetic recording media, a transport speed of the carriers may be increased. However, when a transport speed of the carriers is increased, substrates are likely to fall from the carriers due to vibration during transport or acceleration applied to substrates.

If a supporting force of the support members for supporting a substrate is excessively increased in order to prevent the substrate from falling, the substrate may be deformed and damaged. In particular, in recent years, the number of magnetic recording media housed in a case has been increased by thinning substrates in order to increase the recording capacity of a hard disk device. The thinning of substrates reduces the strength of substrates, and the substrates are easily deformed or damaged.

The substrate holder and the substrate holding method according to the present embodiment suppress substrates from falling from the carriers even when the transport speed of the carriers is increased. Even when the thickness of substrates is reduced, the substrate holder and the substrate holding method according to the present embodiment suppress deformation or breakage of a substrate and scratches in the supported portions of the substrate caused by the support members. Furthermore, the film-forming apparatus according to the present embodiment enhances the productivity in manufacturing recording media by using such a substrate holder.

In the present embodiment, a case where a magnetic recording medium to be mounted on a hard disk device is manufactured using an inline film-forming apparatus that performs a film-forming process while sequentially transporting disc-shaped substrates between a plurality of chambers will be described as an example.

As illustrated in FIG. 1, a magnetic recording medium manufactured by the inline film-forming apparatus according to the present embodiment has a structure in which a soft magnetic layer 81, an intermediate layer 82, a recording magnetic layer 83, and a protective layer 84 are sequentially laminated on respective surfaces of a disc-shaped substrate 9, and a lubricating film 85 is further formed on the outermost surface.

The disc-shaped substrate 9 is not limited to a specific type of substrate, as long as it is a non-magnetic substrate, and any substrate may be used. As the disc-shaped substrate 9, for example, an aluminum alloy substrate such as an Al—Mg alloy containing aluminum as a main component, a substrate made of soda glass, aluminosilicate-based glass or crystallized glass, silicon, titanium, a ceramic, or various resins, or the like is used.

### (Inline Film-Forming Apparatus)

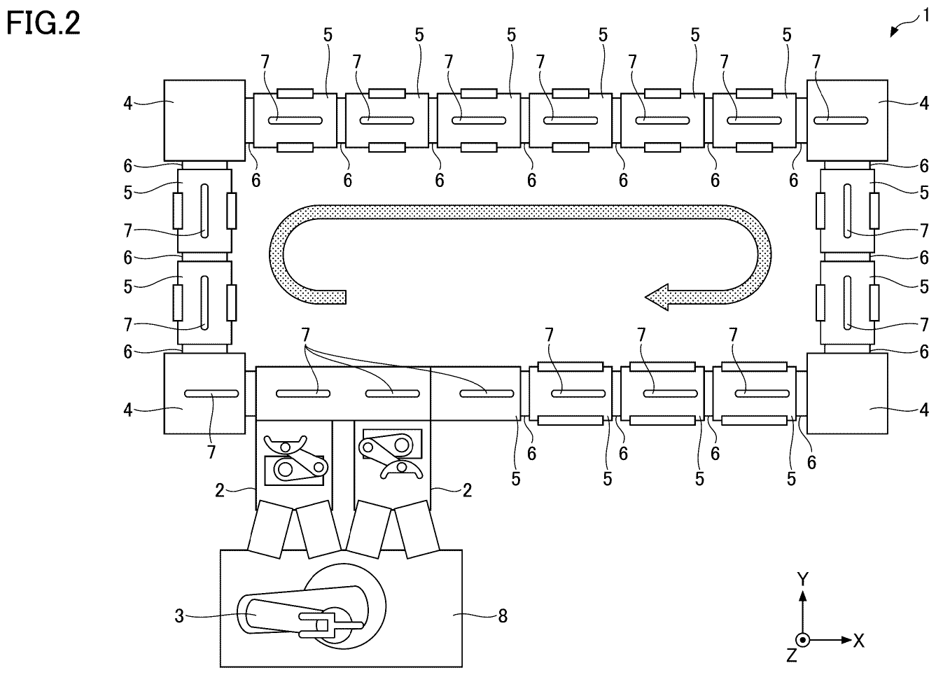

FIG. 2 is a plan view of the inline film-forming apparatus 1 according to the present embodiment. When manufacturing the magnetic recording medium, for example, at least a soft magnetic layer 81, an intermediate layer 82, a recording magnetic layer 83, and a protective layer 84 are sequentially laminated on respective surfaces of a disc-shaped substrate 9 to be subjected to film formation using an inline film-forming apparatus 1 as illustrated in FIG. 2. Through such a process, the magnetic recording medium can be obtained at high productivity.

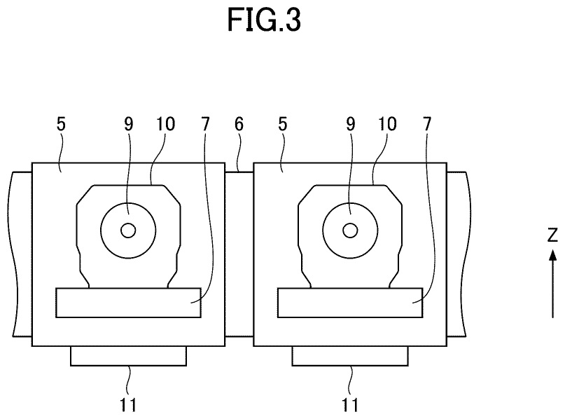

Specifically, the inline film-forming apparatus 1 includes a robot base 8, a substrate cassette transfer robot 3 placed on the robot base 8, a substrate attaching/detaching robot 2 adjacent to the robot base 8, and a plurality of corner chambers 4 for rotating the carriers 7. The inline film-forming apparatus 1 also includes a plurality of chambers 5 disposed between the corner chambers 4, a plurality of carriers 7 transported in the plurality of corner chambers 4 and the plurality of chambers 5, and a transport mechanism 11 (see FIG. 3) for transporting the plurality of carriers 7.

Gate valves 6 are respectively provided at the connecting portions of the chambers 5, and when the gate valves 6 are in a closed state, the inside of each chamber becomes an independent sealed space.

A vacuum pump (not illustrated) is connected to each chamber 5, and the plurality of carriers 7 are sequentially transported by the transport mechanism 11 into each chamber 5 which is made to be in a decompressed state by an operation of the vacuum pump. While the plurality of carriers 7 are sequentially transported, the soft magnetic layer 81, the intermediate layer 82, the recording magnetic layer 83, and the protective layer 84 illustrated in FIG. 1 are sequentially formed on respective surfaces of the disc-shaped substrate 9 held by the carrier 7 in each chamber 5. Thereafter, the disc-shaped substrate 9 is taken out from the inline film-forming apparatus 1, and the lubricating film 85 illustrated in FIG. 1 is formed on respective surfaces of the disc-shaped substrate 9, thereby finally obtaining the magnetic recording medium illustrated in FIG. 1. Each corner chamber 4 is a chamber for changing the moving direction of the carriers 7, and a mechanism for rotating the carriers 7 to move them to the next chamber 5 is provided in the corner chamber 4.

FIG. 3 is a side sectional view of the chambers 5 in the inline film-forming apparatus 1 according to the present embodiment. The inline film-forming apparatus 1 includes, for example, a linear motor driving mechanism configured to be driven in a non-contact state as the transport mechanism 11 that transports the carrier 7. In this linear motor driving mechanism, a plurality of magnets are arranged in the lower portion of the carrier 7 so that N poles and S poles are alternately arranged, and a rotary magnet in which N poles and S poles are alternately arranged in a spiral shape is arranged along the transport path below the magnets of the carrier 7 with a partition wall being interposed between the magnets of the carrier 7 and the rotary magnet. The linear motor drive mechanism transports the carrier 7 by rotating the rotary magnet around the axis while magnetically coupling the magnet on the carrier 7 side and the rotary magnet in a non-contact manner.

### (Method for Manufacturing Magnetic Recording Medium)

A method for manufacturing the magnetic recording medium using the inline film-forming apparatus 1 according to the present embodiment will be described with reference to FIG. 1. The inline film-forming apparatus 1 sequentially transports the disc-shaped substrate 9 held by the carrier 7 between the plurality of chambers 5, and sequentially laminates the soft magnetic layer 81, the intermediate layer 82, the recording magnetic layer 83, and the protective layer 84 on respective surfaces of the disc-shaped substrate 9, thereby manufacturing the magnetic recording medium.

In the method for manufacturing the magnetic recording medium, the inline film-forming apparatus 1 can continuously perform the processes from the formation of the soft magnetic layer 81 to the formation of the protective layer 84 by using one apparatus, and can therefore reduce contamination of the disc-shaped substrate 9 when the disc-shaped substrate 9 as a film-formation target is handled. In addition, the method for manufacturing the magnetic recording medium can reduce the number of handling steps and the like by the inline film-forming apparatus 1 to improve the efficiency of the manufacturing process, and can improve the product yield to increase the productivity in manufacturing the magnetic recording medium.

### (Substrate Holder and Substrate Holding Method)

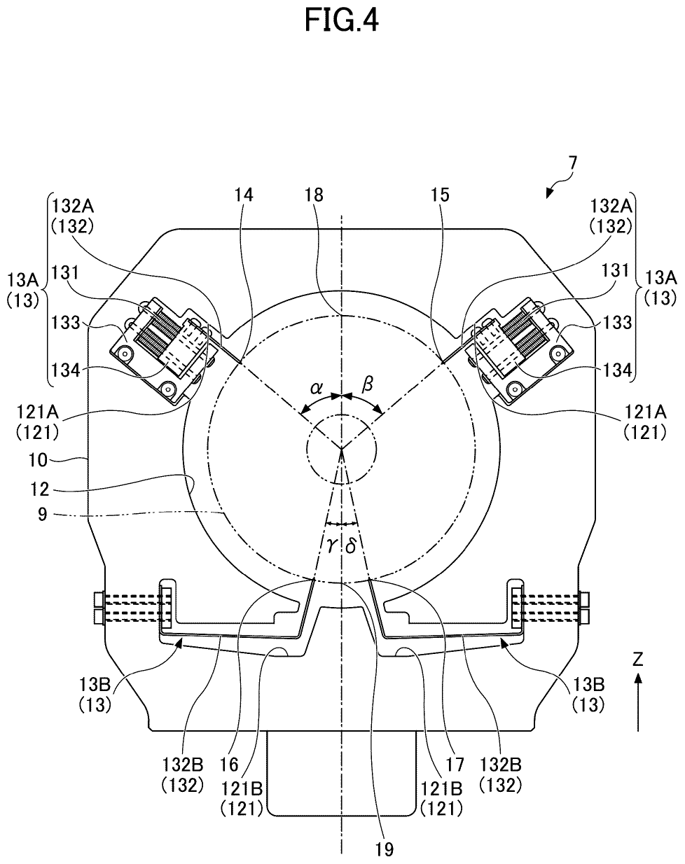

FIG. 4 is a side view of the carrier 7 used in the inline film-forming apparatus 1 according to the present embodiment. The carrier 7 in the present embodiment will be described in more detail with reference to FIG. 4. The carrier 7 is provided with one substrate holder 10 for holding the disc-shaped substrate 9 in a vertical position. The vertical placement means a state in which the main surface (front surface or rear surface) of the disc-shaped substrate 9 is parallel to the gravity direction. The carrier 7 arranges one substrate holder 10 in the transport direction.

The substrate holder 10 has a thickness of about one to several times the thickness of the disc-shaped substrate 9. A circular hole portion 12 having a diameter larger than that of the disc-shaped substrate 9 is provided in the substrate holder 10 such that a gap in the order of 10 mm is formed in the radial direction from the outer peripheral portion of the disc-shaped substrate 9 held by the substrate holder 10.

Four support members 13 are elastically deformably attached to the periphery of the hole portion 12 of each substrate holder 10. The four support members 13 are provided at the periphery of the hole portion 12 of the substrate holder 10 so as to support, at specific positions, the outer peripheral portion of the disc-shaped substrate 9 arranged in the hole portion 12.

The substrate holder 10 can support the outer peripheral portion of the disc-shaped substrate 9 and detachably hold the disc-shaped substrate 9 fitted into the support members 13. The disc-shaped substrate 9 is attached to and detached from the substrate holder 10 by, for example, the substrate attaching/detaching robot 2 pushing down the two support members 13 on the lower side of the substrate holder 10 in the vertical direction.

The substrate holder 10 holds the disc-shaped substrate 9 inside the hole portion 12 by the four support members 13 supporting a first-side outer peripheral edge portion 14, a second-side outer peripheral edge portion 15, a third-side outer peripheral edge portion 16, and a fourth-side outer peripheral edge portion 17 of the disc-shaped substrate 9, respectively. The first-side outer peripheral edge portion 14, the second-side outer peripheral edge portion 15, the third-side outer peripheral edge portion 16, and the fourth-side outer peripheral edge portion 17 of the disc-shaped substrate 9 include at least one of the outer peripheral surface of the disc-shaped substrate 9 or the outer peripheral edge (edge or corner) of the disc-shaped substrate 9.

The proximal end side of the support member 13 is located in a gap 121 formed at a peripheral part of the hole portion 12 of the substrate holder 10, and is fixed to the main body of the substrate holder 10 within the gap 121. The distal end side of the support member 13 protrudes from the gap 121 of the substrate holder 10 toward the inside of the hole portion 12.

The four support members 13 include two first support members 13A and two second support members 13B.

The two first support members 13A support the first-side outer peripheral edge portion 14 located in the upper portion of the disc-shaped substrate 9 with respect to the vertical direction and the second-side outer peripheral edge portion 15 located in the upper portion of the disc-shaped substrate 9 with respect to the vertical direction, respectively. The first-side outer peripheral edge portion 14 is located in the left side of the disc-shaped substrate 9 with respect to the horizontal direction (or on the right side when viewed from the back side of FIG. 4), and the second-side outer peripheral edge portion 15 is located in the right side of the disc-shaped substrate 9 with respect to the horizontal direction (or on the left side when viewed from the back side of FIG. 4).

The first support member 13A includes a coil spring 131, a plate spring member 132A, a fixing portion 133 arranged in a gap 121A, which is the gap 121 of the hole portion 12 and located in the upper portion of the disc-shaped substrate 9 with respect to the vertical direction, and a coupling portion 134 coupling the coil spring 131 and the plate spring member 132A.

The coil spring 131 is arranged at a fixing portion 133 disposed within the gap 121A of the hole portion 12 and is fixed to the main body of the substrate holder 10 via the fixing portion 133. One end of the coil spring 131 is coupled to the coupling portion 134.

The plate spring member 132A is formed in a plate shape, with one end thereof being coupled to the coupling portion 134 within the gap 121A of the hole portion 12, and having a shape protruding from the gap 121A toward the inside of the hole portion 12.

The fixing portion 133 is arranged in the gap 121A of the hole portion 12 and is fixed to the main body of the substrate holder 10.

The coupling portion 134 is arranged at the fixing portion 133 in the gap 121A of the hole portion 12, and couples the coil spring 131 and the plate spring member 132A in the fixing portion 133.

The two second support members 13B support the third-side outer peripheral edge portion 16 located in the lower portion of the disc-shaped substrate 9 with respect to the vertical direction and the fourth-side outer peripheral edge portion 17 located in the lower portion of the disc-shaped substrate 9 with respect to the vertical direction, respectively. The third-side outer peripheral edge portion 16 is located in the left side of the disc-shaped substrate 9 with respect to the horizontal direction (or on the right side when viewed from the back side of FIG. 4), and the fourth-side outer peripheral edge portion 17 is located in the right side of the disc-shaped substrate 9 with respect to the horizontal direction (or on the left side when viewed from the back side of FIG. 4).

The second support member 13B includes a plate spring member 132B bent in a substantially L shape.

The plate spring member 132B has a shape protruding toward the inside of the hole portion 12 from a gap 121B, which is the gap 121 of the hole portion 12 and located in the lower portion of the disc-shaped substrate 9 with respect to the vertical direction.

The distal end portions of the support members 13 (the distal end portions of the plate spring members 132A and 132B) may be provided with, for example, a V-shaped or U-shaped groove portion that engages with the outer peripheral portion of the disc-shaped substrate 9 and suppresses the disc-shaped substrate 9 from falling.

The spring constant of the coil spring 131 is preferably 0.2 N/mm to 8.0 N/mm. The lower limit of the spring constant of the coil spring 131 is more preferably 1.0 N/mm or more, and further preferably 3.0 N/mm or more. The upper limit of the spring constant of the coil spring 131 is more preferably 7.0 N/mm or less, and further preferably 6.0 N/mm or less. By setting the spring constant of the coil spring 131 within the above-described preferable range, the effect of suppressing falling of the disc-shaped substrate 9 can be further enhanced, and the effect of suppressing deformation or breakage of the disc-shaped substrate 9 and an occurrence of scratches on the disc-shaped substrate 9 can be further enhanced.

The spring constant of the plate spring member 132A is not particularly limited, and may be designed to have any appropriate magnitude. Since the plate spring member 132A is attached to the coil spring 131, the plate spring member 132A preferably has high rigidity. The rigidity of the plate spring member 132A is preferably higher than that of the coil spring 131 or the plate spring member 132B, for example. If the rigidity of the plate spring member 132A is high, sliding of the disc-shaped substrate 9 during the transport is suppressed, and an occurrence of scratches on the disc-shaped substrate 9 can be suppressed.

The spring constant of the plate spring member 132B is preferably 0.2 N/mm to 8.0 N/mm, similarly to the spring constant of the coil spring 131. The lower limit of the spring constant of the plate spring member 132B is more preferably 1.0 N/mm or more, and further preferably 3.0 N/mm or more, similarly to the coil spring 131. The upper limit of the spring constant of the plate spring member 132B is more preferably 7.0 N/mm or less, and further preferably 6.0 N/mm or less, similarly to the coil spring 131. By setting the spring constant of the plate spring member 132B within the above-described preferable range, the effect of suppressing falling of the disc-shaped substrate 9 can be further enhanced, and the effect of suppressing deformation or breakage of the disc-shaped substrate 9 and an occurrence of scratches on the disc-shaped substrate 9 can be further enhanced.

The support member 13 may be made of a heat-resistant alloy containing any of iron, nickel, cobalt, molybdenum, tungsten, and the like as a main component. The supporting force of the support member 13 for the disc-shaped substrate 9 is appropriately selected depending on the materials and thicknesses of the disc-shaped substrate 9, and is, for example, 2 N to 6 N.

A first central angle α of the disc-shaped substrate 9 between the first-side outer peripheral edge portion 14 located in the upper portion of the disc-shaped substrate 9 with respect to the vertical direction and the uppermost peripheral edge portion 18 located in the uppermost portion of the disc-shaped substrate 9 with respect to the vertical direction is 30° to 65°. The lower limit of the first central angle α is preferably 35° or more, more preferably 40° or more, and still more preferably 45° or more. The upper limit of the first central angle α is preferably 60° or less, more preferably 55° or less, and still more preferably 50° or less.

A second central angle β of the disc-shaped substrate 9 between the second-side outer peripheral edge portion 15 located in the upper portion of the disc-shaped substrate 9 with respect to the vertical direction and the uppermost peripheral edge portion 18 located in the uppermost portion of the disc-shaped substrate 9 with respect to the vertical direction is 30° to 65°, similarly to the first central angle α, and is preferably the same angle as the first central angle α. The lower limit of the second central angle β is preferably 35° or more, more preferably 40° or more, and still more preferably 45° or more, similarly to the first central angle α. The upper limit of the second central angle β is preferably 60° or less, more preferably 55° or less, and still more preferably 50° or less, similarly to the first central angle α.

A third central angle γ of the disc-shaped substrate 9 between the third-side outer peripheral edge portion 16 located in the upper portion of the disc-shaped substrate 9 with respect to the vertical direction and the lowermost peripheral edge portion 19 located in the lowermost portion of the disc-shaped substrate 9 with respect to the vertical direction is 10° to 20°. The lower limit of the third central angle γ is preferably 12° or more, and more preferably 13° or more. The upper limit of the third central angle γ is preferably 18° or less, and more preferably 15° or less.

A fourth central angle δ of the disc-shaped substrate 9 between the fourth-side outer peripheral edge portion 17 located in the lower portion of the disc-shaped substrate 9 with respect to the vertical direction and the lowermost peripheral edge portion 19 located in the lowermost portion of the disc-shaped substrate 9 with respect to the vertical direction is 10° to 20°, similarly to the third central angle γ, and is preferably the same angle as the third central angle γ. The lower limit of the fourth central angle δ is preferably 12° or more, and more preferably 13° or more, similarly to the third central angle γ. The upper limit of the fourth central angle & is preferably 18° or less, and more preferably 15° or less.

In other words, the first central angle α and the second central angle β of the disc-shaped substrate 9 are both equal to or larger than the third central angle γ and the fourth central angle δ of the disc-shaped substrate 9.

It is preferable that the support members 13 do not support the disc-shaped substrate 9 at a portion of the disc-shaped substrate 9 except for the range of the first central angle α and the second central angle β of the disc-shaped substrate 9 and the range of the third central angle γ and the fourth central angle δ of the disc-shaped substrate 9.

By using the substrate holder 10 having such support members 13, even if the transport speed of the carrier 7 is increased, the disc-shaped substrate 9 is prevented from falling from the carrier 7, and deformation or breakage and scratches in the supported portions of the disc-shaped substrate 9 caused by the support member 13 are suppressed. Therefore, the inline film-forming apparatus 1 can increase productivity in manufacturing the magnetic recording medium. Since deformation or breakage of the disc-shaped substrate 9 and an occurrence of scratches are suppressed, it is possible to provide the inline film-forming apparatus 1 capable of accommodating the thinning of the disc-shaped substrate 9.

The reason for the above-described operation and effect by using the substrate holder 10 is considered as follows. When the transport speed of the carrier 7 is increased, strong vibration and acceleration are applied to the disc-shaped substrate 9. The vibration and acceleration applied to the disc-shaped substrate 9 have a strong component particularly in a direction parallel to the traveling direction of the carrier 7, and such a component causes the substrate to fall or deform. The substrate holder 10 can mitigate the force applied in the traveling direction of the carrier 7 and suppress the disc-shaped substrate 9 from falling by supporting the disc-shaped substrate 9 at specific positions near the uppermost peripheral edge portion 18 and the lowermost peripheral edge portion 19 of the disc-shaped substrate 9. The substrate holder 10 can suppress deformation of the disc-shaped substrate 9 because the support members 13 do not support the disc-shaped substrate 9 except at specific positions near the uppermost peripheral edge portion 18 and the lowermost peripheral edge portion 19 of the disc-shaped substrate 9.

On the other hand, in the case where the two support members 13 support the first-side outer peripheral edge portion 14 and the second-side outer peripheral edge portion 15 of the disc-shaped substrate 9 in a range where the first central angle α and the second central angle β of the disc-shaped substrate 9 are smaller than 30°, the holding force of the substrate holder 10 for the disc-shaped substrate 9 decreases. Then, the disc-shaped substrate 9 is likely to fall from the substrate holder 10.

In the case where the two support members 13 support the first-side outer peripheral edge portion 14 and the second-side outer peripheral edge portion 15 of the disc-shaped substrate 9 in a range where the first central angle α and the second central angle β of the disc-shaped substrate 9 are larger than 65°, deformation of the supported portions of the disc-shaped substrate 9 by the two support members 13 is likely to occur.

Furthermore, in the case where the other two support members 13 support the third-side outer peripheral edge portion 16 and the fourth-side outer peripheral edge portion 17 of the disc-shaped substrate 9 in a range where the third central angle γ and the fourth central angle δ of the disc-shaped substrate 9 are smaller than 10°, the holding force of the substrate holder 10 for the disc-shaped substrate 9 decreases. Then, the disc-shaped substrate 9 is likely to fall from the substrate holder 10.

In the case where the other two support members 13 support the third-side outer peripheral edge portion 16 and the fourth-side outer peripheral edge portion 17 of the disc-shaped substrate 9 in a range where the third central angle γ and the fourth central angle δ of the disc-shaped substrate 9 are larger than 20°, deformation of the support portion of the disc-shaped substrate 9 by the support members 13 is likely to occur.

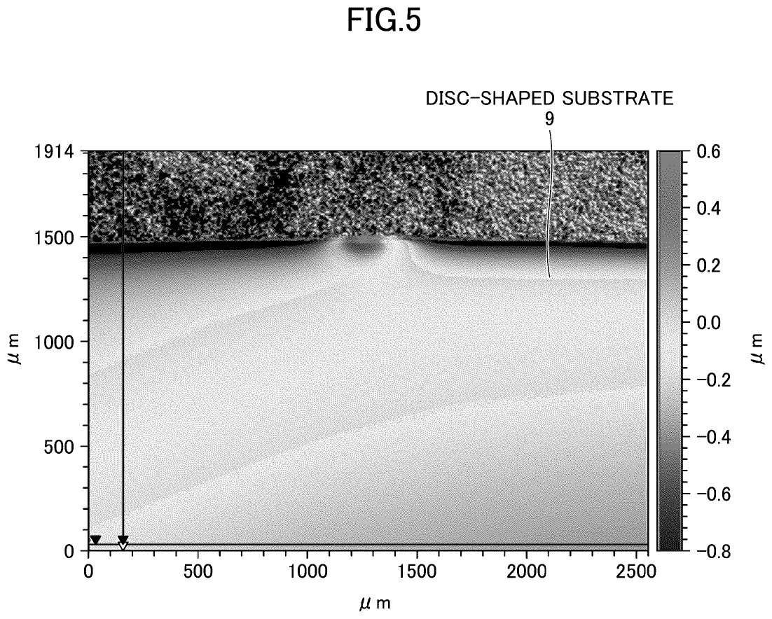

The deformation of the disc-shaped substrate 9 includes deformation that is difficult to distinguish with the naked eye. FIG. 5 illustrates a microscopic image illustrating an example of deformation generated in the disc-shaped substrate 9. As illustrated in FIG. 5, the disc-shaped substrate 9 is deformed so that it is difficult to distinguish the deformation with the naked eye. The deformation of the disc-shaped substrate 9 is a depression (i.e., dent) which is plastically deformed by the supporting force of the support member provided in a conventional substrate holder. The dent has a height of about 1.26 μm and a width of about 180.15 μm from the outermost peripheral edge of the disc-shaped substrate 9. In recent years, in order to meet the demand for increasing the recording capacity of hard disk drives, the recording area of a magnetic recording medium has been expanded to its outer peripheral portion. Under such circumstances, a minute dent which cannot be recognized with the naked eye as illustrated in FIG. 5 is also determined as a defective portion. By using the substrate holder 10 according to the present embodiment, deformation of the supported portions of the disc-shaped substrate 9 caused by the support members 13 can be suppressed.

According to the substrate holder 10 and the substrate holding method of the present embodiment, even when the transport speed of the carrier 7 is increased, the disc-shaped substrate 9 can be prevented from falling from the substrate holder 10. Even if the thickness of the disc-shaped substrate 9 is reduced, deformation of the disc-shaped substrate 9 at the supported portions of the disc-shaped substrate 9 caused by the support members 13 can be suppressed. Furthermore, the inline film-forming apparatus 1 that can achieve high productivity can be provided. Since deformation of the disc-shaped substrate 9 is suppressed, the inline film-forming apparatus 1 capable of accommodating the thinning of the disc-shaped substrate 9 can be provided.

Although the preferred embodiments have been described in detail, the present disclosure is not limited to the above-described embodiments, and various modifications and substitutions can be made to the above-described embodiments without departing from the scope of the appended claims. For example, the film-forming apparatus including the substrate holder 10 according to the present embodiment is not limited to the inline film-forming apparatus 1, and can be applied to a batch film-forming apparatus or the like. The number of the support members 13 is not limited as long as it is four or more.

The numbers such as ordinal numbers and quantities used in the description of the embodiments are all examples for specifically describing the technique of the present disclosure, and the present disclosure is not limited to the exemplified numbers. The connection relationship between the constituent elements is an example for specifically describing the technique of the present disclosure, and the connection relationship for realizing the functions of the present disclosure is not limited thereto.

### Examples

Hereinafter, advantageous effects of the substrate holder 10 and the inline film-forming apparatus 1 according to the present embodiment will be more apparent by way of examples. The substrate holder 10 and the inline film-forming apparatus 1 according to the present embodiment are not limited to the following examples, and can be implemented by being appropriately changed within a range not changing the gist.

### Example 1

### (Transport of Disc-Shaped Substrate 9)

In Example 1, magnetic recording media having the layer structure illustrated in FIG. 1 were manufactured from disc-shaped substrates 9 (outside diameter: 96 mm, inside diameter: 25 mm, depth: 0.7 mm) made of an aluminum alloy by using the inline film-forming apparatus 1 illustrated in FIG. 2 and the carriers 7 illustrated in FIG. 4. In particular, a FeCoB alloy as the soft magnetic layers 81, Ru as the intermediate layers 82, and a 70Co-5Cr-15 Pt-10SiO₂ alloy as the recording magnetic layers 83 were laminated on respective surfaces of the disc-shaped substrate 9 by using a direct-current (DC) sputtering method. In addition, a hard carbon film was laminated as the protective layers 84 on the recording magnetic layers 83 by using an ion beam method.

The two second support members 13A in the upper portion of the substrate holder 10 supported the first-side outer peripheral edge portion 14 and the second-side outer peripheral edge portion 15 of the disc-shaped substrate 9 at respective positions where the first central angle α and the second central angle β of the disc-shaped substrate 9 were 50°, respectively. The two second support members 13B on the lower portion of the substrate holder 10 supported the third-side outer peripheral edge portion 16 and the fourth-side outer peripheral edge portion 17 of the disc-shaped substrate 9 at respective positions where the third central angle γ and the fourth central angle δ of the disc-shaped substrate 9 were 13°, respectively.

The coil spring 131 of the first support member 13A had a spring constant of 5.0 N/mm, a free distance of 15 mm, a length of 11 mm in the substrate holder 10, and a pushing amount of 1 mm when the disc-shaped substrate 9 was held.

The spring constant of the plate spring member 13B of the second support member 132B was set to 5.0 N/mm.

The transfer speed of the carriers 7 between the chambers 5 was 1.2 m/sec, and the rate of acceleration during the acceleration and deceleration was 6 m/sec².

Table 1 shows the sizes of the central angles (first central angle α, second central angle β, third central angle γ, and fourth central angle δ) of the support members 13 (first support member 13A and second support member 13B) of the disc-shaped substrate 9, which indicate the supported positions where the support members 13 support in the disc-shaped substrate 9, the spring constants of the coil springs 131 and the plate spring members 132B, the thickness of the disc-shaped substrate 9, the transport speed of the carriers 7, and the accelerations during acceleration and deceleration.

### (Evaluation)

### (Presence or Absence of Fall of Disc-shaped Substrate)

Under the above conditions, 1,000 magnetic recording media were manufactured, but the disc-shaped substrate 9 did not fall.

### (Incidence of Dents)

The presence or absence of deformation (dents) in the outer peripheral edge of the magnetic recording medium manufactured under the above conditions was determined by a differential interference microscope image, and when the magnetic recording medium was observed from the surface side (data surface side) and deformation of 100 μm or more in width and 0.5 μm or more in height from the outer peripheral edge was observed, it was determined that dents had occurred.

### (Incidence of Scratches)

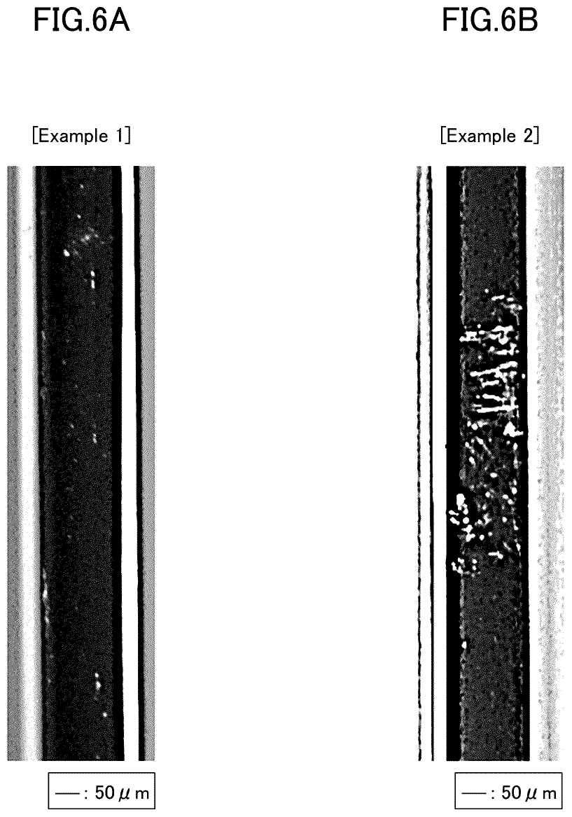

The presence or absence of scratches at the outer peripheral edge of the magnetic recording medium manufactured under the above conditions was determined by a differential interference microscope image, and when scratches having a width of 60 μm or more were observed in the thickness direction of the magnetic recording medium, it was determined that scratches had been generated. FIG. 6A illustrates a microscopic image of the disc-shaped substrate 9 observed from the thickness direction. In FIG. 6A, the black vertical linear portion are the edge surface of the disc-shaped substrate 9, and the sides next to the black portion are the edge surface out of focus. In FIG. 6A, white portions in black vertical linear portion are scratches generated in the edge surface. As illustrated in FIG. 6A, the disc-shaped substrate 9 held and transported by the substrate holder 10 had almost no scratches.

Table 1 shows the results of the presence or absence of a fall of the disc-shaped substrate 9, the incidence of dents, and the incidence of scratches. In addition, in Table 1, as to the presence or absence of a fall of the disc-shaped substrate 9, the case where the disc-shaped substrate 9 did not fall is indicated by “A”, and the case where the disc-shaped substrate 9 fell is indicated by “B”.

### Examples 2 to 15 and Comparative Examples 1 to 6

The same procedure as in Example 1 was performed except that the conditions were changed to those shown in Table 1. Table 1 shows various transport conditions of the disc-shaped substrates 9 in the substrate holder 10 (the sizes of the central angles of the disc-shaped substrates 9 with respect to the support members 13 (the first central angle α, the second central angle β, the third central angle γ, and the fourth central angle δ), the spring constants of the coil springs 131 and the plate spring members 132A, the thickness of the disc-shaped substrate 9, and the transport speed and the acceleration of the carriers 7). Table 1 shows the evaluation results (the presence or absence of the fall of the disc-shaped substrate 9, the incidence of dents, and the incidence of scratches) of the examples and comparative examples. In addition, in Table 1, the numerical values in bold type indicate that the values are within the range of the present embodiment, and the italicized numerical values indicate that the values are outside the range of the present embodiment.

FIG. 6B illustrates a microscopic image of the disc-shaped substrate 9 held and transported by the substrate holder of Comparative Example 1, which was observed from the thickness direction. As illustrated in FIG. 6B, it was confirmed that scratches were generated at the edge of the disc-shaped substrate 9 held and transported by the substrate holder of Comparative Example 1.

TABLE 1

| | Support member | | | | | | | | | | | |
|---|---|---|---|---|---|---|---|---|---|---|---|---|
| | | | | | Coil | Plate spring | | | | | | |
| | | | | | spring | member of | | Conditions of | | | | |
| | | | | | of first | second | Disc- | carrier transport | | Presence/ | | |
| | Size of central angle | | | | support | support | shaped | | Acceleration | absence | In- | In- |
| | of each support | | | | member | member | substrate | | during | of disc- | cidence | cidence |
| | member with respect | | | | Spring | Spring | Thick- | Transport | acceleration/ | shaped | of | of |
| | to disc-shaped substrate | | | | constant | constant | ness | speed | deceleration | substrate | dents | scratches |
| | α[°] | β[°] | γ[°] | δ[°] | [N/mm] | [N/mm] | [mm] | [m/second] | [m/second²] | fall | [%] | [%] |
| Example 1 | 50 | 50 | 13 | 13 | 5.0 | 5.0 | 0.7 | 1.2 | 6 | A | 0.0 | 0.0 |
| Example 2 | 40 | 40 | 13 | 13 | 5.0 | 5.0 | 0.7 | 1.2 | 6 | A | 0.0 | 2.0 |
| Example 3 | 30 | 30 | 13 | 13 | 5.0 | 5.0 | 0.7 | 1.2 | 6 | A | 0.0 | 4.0 |
| Example 4 | 65 | 65 | 13 | 13 | 5.0 | 5.0 | 0.7 | 1.2 | 6 | A | 1.0 | 0.0 |
| Example 5 | 50 | 50 | 10 | 10 | 5.0 | 5.0 | 0.7 | 1.2 | 6 | A | 0.0 | 2.0 |
| Example 6 | 50 | 50 | 20 | 20 | 5.0 | 5.0 | 0.7 | 1.2 | 6 | A | 0.5 | 0.0 |
| Example 7 | 50 | 50 | 13 | 13 | 6.0 | 6.0 | 0.7 | 1.2 | 6 | A | 0.5 | 0.0 |
| Example 8 | 50 | 50 | 13 | 13 | 7.0 | 7.0 | 0.7 | 1.2 | 6 | A | 0.5 | 0.0 |
| Example 9 | 50 | 50 | 13 | 13 | 8.0 | 8.0 | 0.7 | 1.2 | 6 | A | 1.0 | 0.0 |
| Example 10 | 50 | 50 | 13 | 13 | 4.0 | 4.0 | 0.7 | 1.2 | 6 | A | 0.0 | 0.5 |
| Example 11 | 50 | 50 | 13 | 13 | 1.0 | 1.0 | 0.7 | 1.2 | 6 | A | 0.0 | 2.0 |
| Example 12 | 50 | 50 | 13 | 13 | 0.2 | 0.2 | 0.7 | 1.2 | 6 | A | 0.0 | 3.0 |
| Example 13 | 50 | 50 | 13 | 13 | 5.0 | 5.0 | 0.7 | 1.8 | 7 | A | 1.0 | 1.0 |
| Example 14 | 50 | 50 | 13 | 13 | 5.0 | 5.0 | 0.6 | 1.2 | 6 | A | 1.0 | 0.0 |
| Example 15 | 50 | 50 | 13 | 13 | 5.0 | 5.0 | 0.5 | 1.2 | 6 | A | 1.0 | 0.0 |
| Comparative | 25 | 25 | 13 | 13 | 5.0 | 5.0 | 0.7 | 1.2 | 6 | B | 0.0 | 6.0 |
| Example 1 | | | | | | | | | | | | |
| Comparative | 70 | 70 | 13 | 13 | 5.0 | 5.0 | 0.7 | 1.2 | 6 | B | 3.0 | 0.0 |
| Example 2 | | | | | | | | | | | | |
| Comparative | 50 | 50 | 8 | 8 | 5.0 | 5.0 | 0.7 | 1.2 | 6 | B | 0.0 | 5.0 |
| Example 3 | | | | | | | | | | | | |
| Comparative | 50 | 50 | 22 | 22 | 5.0 | 5.0 | 0.7 | 1.2 | 6 | A | 2.0 | 0.0 |
| Example 4 | | | | | | | | | | | | |
| Comparative | 50 | 50 | 13 | 13 | 0.1 | 0.1 | 0.7 | 1.2 | 6 | B | 0.0 | 5.0 |
| Example 5 | | | | | | | | | | | | |
| Comparative | 50 | 50 | 13 | 13 | 8.5 | 8.5 | 0.7 | 1.2 | 6 | A | 19.0 | 0.0 |
| Example 6 | | | | | | | | | | | | |

As shown in Table 1, in each of the examples, the disc-shaped substrate 9 did not fall, the incidence of dents was suppressed to 1.0% or less, and the incidence of scratches was suppressed to 4% or less. In each of the comparative examples, on the other hand, at least one of the following was observed: the disc-shaped substrate 9 fell; the incidence of dents was 2.0% or more; and the incidence of scratches was 5% or more.

Therefore, it was confirmed that by setting the first central angle α and the second central angle β of the disc-shaped substrate 9, which are the supported positions of the two first support members 13A in the upper portion of the substrate holder 10, to 30° to 65°, and setting the third central angle γ and the fourth central angle δ of the disc-shaped substrate 9, which are the support positions of the two second support members 13B in the lower portion of the substrate holder 10, to 10° to 20°, the disc-shaped substrate 9 can be prevented from falling and the disc-shaped substrate 9 can be suppressed from being deformed or damaged and from having scratches.

Therefore, the substrate holder 10 according to the present embodiment can be suitably used as a substrate holder used in a film-forming apparatus for manufacturing a magnetic recording medium from the disc-shaped substrate 9, particularly an inline film-forming apparatus, and it can be said that the magnetic recording medium can be effectively manufactured with an excellent yield.

What is claimed is:

1. A substrate holder, comprising:
a hole portion in which a disc-shaped substrate is vertically disposed; and
at least four support members attached to a periphery of the hole portion in an elastically deformable manner, wherein
two first support members of the four support members support the disc-shaped substrate at a first-side outer peripheral edge portion and a second-side outer peripheral edge portion of the disc-shaped substrate located in an upper portion of the disc-shaped substrate with respect to a vertical direction, and
two second support members of the four support members support the disc-shaped substrate at a third-side outer peripheral edge portion and a fourth-side outer peripheral edge portion of the disc-shaped substrate located in a lower portion of the disc-shaped substrate with respect to the vertical direction, and
a central angle of the disc-shaped substrate between an uppermost peripheral edge portion of the disc-shaped substrate located in an uppermost portion of the disc-shaped substrate with respect to the vertical direction and each of the first-side outer peripheral edge portion and the second-side outer peripheral edge portion is 30° to 65°, and
a central angle of the disc-shaped substrate between a lowermost peripheral edge portion of the disc-shaped substrate located in a lowermost portion of the disc-shaped substrate with respect to the vertical direction and each of the third-side outer peripheral edge portion and the fourth-side outer peripheral edge portion is 10° to 20°.

2. The substrate holder of claim 1, wherein
the support member does not support the disc-shaped substrate at a portion of the disc-shaped substrate except for
a range of the central angle of the disc-shaped substrate between the uppermost peripheral edge portion of the disc-shaped substrate and each of the first-side outer peripheral edge portion and the second-side outer peripheral edge portion, and
a range of the central angle of the disc-shaped substrate between the lowermost peripheral edge portion of the disc-shaped substrate and each of the third-side outer peripheral edge portion and the fourth-side outer peripheral edge portion.

3. The substrate holder of claim 1, wherein
a first support member includes
a coil spring arranged within a gap formed at a peripheral part of the hole portion, and
a plate spring member that is coupled to the coil spring within the gap and protrudes from the gap toward an inside of the hole portion, the first support member being from among the two first support members.

4. The substrate holder of claim 3, wherein
a spring constant of the coil spring is 0.2 N/mm to 8.0 N/mm.

5. The substrate holder of claim 1, wherein
a second support member has a shape bent in an L shape, the second support member being from among the two second support members, and
the spring constant of the second support member is 0.2 N/mm to 8.0 N/mm.

6. A substrate holding method by a substrate holder, the method comprising:
a step of supporting, by the substrate holder, a disc-shaped substrate at a first-side outer peripheral edge portion and a second-side outer peripheral edge portion of the disc-shaped substrate located in an upper portion of the disc-shaped substrate with respect to a vertical direction by two support members of at least four support members attached to a periphery of a hole portion in an elastically deformable manner, the disc-shaped substrate being vertically disposed at the hole portion;
a step of supporting, by the substrate holder, the disc-shaped substrate at a third-side outer peripheral edge portion and a fourth-side outer peripheral edge portion of the disc-shaped substrate located in a lower portion of the disc-shaped substrate with respect to the vertical direction by other two support members of the fourth support members, wherein
a central angle of the disc-shaped substrate between an uppermost peripheral edge portion of the disc-shaped substrate located in an uppermost portion of the disc-shaped substrate with respect to the vertical direction and each of the first-side outer peripheral edge portion and the second-side outer peripheral edge portion and is 30° to 65°, and
a central angle of the disc-shaped substrate between a lowermost peripheral edge portion of the disc-shaped substrate located in a lowermost portion of the disc-shaped substrate with respect to the vertical direction and each of the third-side outer peripheral edge portion and the fourth-side outer peripheral edge portion is 10° to 20°.

7. A film-forming apparatus, comprising:
a chamber configured to perform a film-forming process on a disc-shaped substrate;
a carrier provided with the substrate holder of claim 1 for holding the disc-shaped substrate at least within the chamber; and
a transport mechanism configured to transport the carrier.
